(19) United States
(12) Patent Application Publication
(10) Pub. No.: US 2005/0194960 A1
(43) Pub. Date: Sep. 8, 2005

(54) Broadband subharmonic sampling phase detector

(76) Inventor: Reza Tayrani, Marina Del Rey, CA (US)

Correspondence Address: Leonard A. Alkov, Esq.;Raytheon Company, P.O. Box 902 (E4/N119), El Segundo, CA, 90245-0902, US

(21) Appl. No.: 10/792,959

(22) Filed: Mar. 4, 2004

(51) Int. Cl. H03D 13/00; G01R 25/00; B23D 63/00; H03D 3/00; H04L 27/14

(52) U.S. Cl. 324/76.77

(57) ABSTRACT

A phase detector and method of phase detection. The detector includes a substrate; an impulse generator fabricated on the substrate; and a sampling circuit operationally coupled to the generator and disposed on the substrate. In the best mode, the impulse generator and the sampling circuit are fabricated on the substrate using grounded slotline technology and coplanar waveguide technology. In more specific embodiments, the generator is a slotline impulse generator with a step recovery diode. In this embodiment, the impulse generator further includes a coplanar waveguide to slotline transition at an input port thereof and a slotline to coplanar waveguide at an output port thereof. In addition, in the illustrative embodiment, the sampling circuit further includes a slotline hybrid T junction. In accordance with the present teachings, the junction is an ultra-wideband grounded slotline hybrid T junction. The sampling circuit further includes a phase bridge coupled to the hybrid T junction and a grounded slotline coupled delay. In the specific embodiment, the sampling circuit also includes a broadband transition from coplanar waveguide to coupled slotline.

### BACKGROUND OF THE INVENTION

1. Field of the Invention

The present invention relates to electrical and electronic circuits and systems. More specifically, the present invention relates to sub-harmonic sampling phase detectors.

2. Description of the Related Art

Sub-harmonic sampling phase detectors or sampling circuits are used in both commercial and defense applications. Typical commercial applications include frequency counting, network analysis, and in sampling oscilloscopes to view high frequency waveforms. Typical defense applications include phase locked loops and as the heart of programmable harmonic phase comparators (PHPCs) MIC (Microwave Integrated Circuit) in the exciter units of FA-18, F15 and other similar airborne platforms. The PHPC MIC in turn is a critical unit of the Frequency Agile Microwave Reference (FAMR) unit that is part of the exciter within a radar system.

Unfortunately, conventional sub-harmonic sampling phase detectors are too bandwidth limited to meet the demands of many current applications. In addition, conventional sub-harmonic sampling phase detectors require the use of a balun and therefore tend to be too large and bulky for many current applications. Further, the overall performance of conventional sub-harmonic sampling phase detectors tends to be inadequate with regard to efficiency, power consumption, reliability, parts count, produce-ability and ease of integration.

Hence, a need exists in the art for a sub-harmonic sampling phase detector that is smaller, more compact with a wider-operational bandwidth that offer improved performance with respect to efficiency, power consumption, reliability, parts count, produce-ability and ease of integration.

### SUMMARY OF THE INVENTION

The need in the art is addressed by the phase detector and method of phase detection of the present invention. Generally, the inventive detector includes a substrate; an impulse generator fabricated on the substrate; and a sampling circuit operationally coupled to the generator and disposed on the substrate.

In the best mode, the impulse generator and the sampling circuit are fabricated on the substrate using grounded slotline technology and coplanar waveguide technology. In more specific embodiments, the generator is a slotline impulse generator with a step recovery diode. In this embodiment, the impulse generator further includes a coplanar waveguide to slotline transition at an input port thereof and a slotline to coplanar waveguide at an output port thereof. The inventive impulse generator has inherent amplitude and phase differential properties that are most useful for the design of a miniature broadband sampling phase detector.

In the illustrative embodiment, the sampling circuit further includes a slotline hybrid T junction. In accordance with the present teachings, the junction is an ultra-wideband grounded slotline hybrid T junction. The sampling circuit further includes a phase bridge coupled to the hybrid T junction and a grounded slotline coupled delay. In the specific embodiment, the sampling circuit also includes a broadband transition from coplanar waveguide to coupled slotline. Preferably, the substrate is a multi-layer alumina structure. A video amplifier is coupled to the sampling circuit.

A programmable sampling phase detector is also disclosed. The inventive programmable sampling phase detector includes a phase detector; a power amplifier coupled to an input of the phase detector; an analog to digital converter coupled to an output of the phase detector; a processor coupled to the analog to digital converter; and a digital to analog converter coupled to the processor and the amplifier.

### BRIEF DESCRIPTION OF THE DRAWINGS

FIG. 1 is a functional block diagram of a sub-harmonic sampling phase detector implemented in accordance with conventional teachings.

FIG. 2 is a block diagram showing a broadband sub-harmonic sampling phase detector.

FIG. 3 is a diagram of a slotline impulse generator comprised of CPW to slotline transitions at the input and output ports and a slotline hybrid T junction.

FIG. 4 is an equivalent circuit representation of the impulse generator shown in FIG. 3.

FIG. 5 is a diagram showing a layout of an illustrative implementation of the hybrid T junction and the phase bridge of the inventive phase detector.

FIG. 6 is an equivalent circuit representation of the phase bridge of FIG. 5.

FIG. 7 is a diagram showing a layout of an illustrative implementation a fully integrated broadband sampling phase detector.

FIG. 8 is a picture of the fully fabricated broadband sampling phase detector using Alumina substrate.

FIG. 9 is a diagram of the smart sampling phase detector.

### DESCRIPTION OF THE INVENTION

Illustrative embodiments and exemplary applications will now be described with reference to the accompanying drawings to disclose the advantageous teachings of the present invention.

While the present invention is described herein with reference to illustrative embodiments for particular applications, it should be understood that the invention is not limited thereto. Those having ordinary skill in the art and access to the teachings provided herein will recognize additional modifications, applications, and embodiments within the scope thereof and additional fields in which the present invention would be of significant utility.

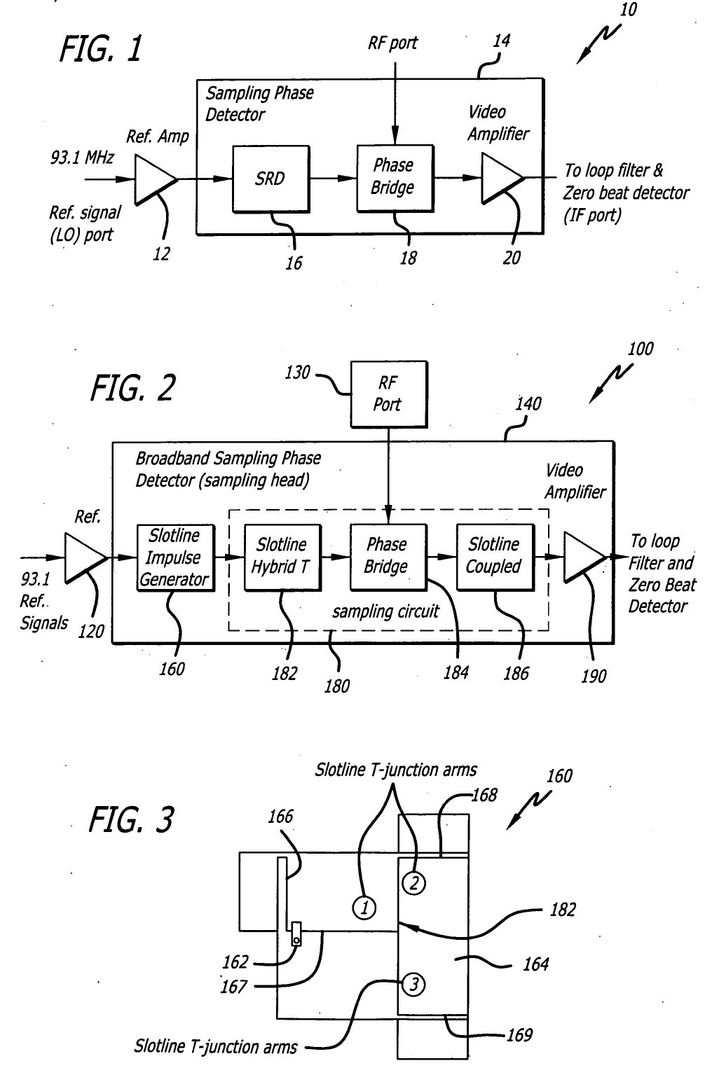

FIG. 1 is a functional block diagram of a sub-harmonic sampling phase detector implemented in accordance with conventional teachings. The conventional phase detector 10 includes a reference amplifier 12 and a sampling phase detector 14. The sampling phase detector 14 includes a step recovery diode (SRD) 16, a phase bridge 18 and a video amplifier 20.

In general, the conventional sub-harmonic sampling phase detector 10 functions as a sampler by taking a sample of voltage controlled oscillator (VCO) signal from the RF port at the rate of reference frequency (e.g. 93.1 MHz) via a local oscillator (LO) port. The step recovery diode 16 is placed across a balanced transmission line. The input reference signal is amplified to a level that triggers the step recovery diode 16. The generated train of impulses, in turn, gates the phase bridge 18 creating a sampling window that samples the VCO signal to produce a video band (IF) output. The resulting video output frequency is the difference between the VCO output signal and some harmonics of the reference (LO). When a multiple of the reference and the RF input are identical in frequency, a zero beat results at the video (IF) output via the video amplifier 20. This is an indication that the reference signal is sampling the RF signal at exactly the same portion of the RF signal from sample to sample. The highest video output frequency from the sampling phase detector will be one half of the reference frequency (e.g., 46.55 MHz). This frequency occurs when the RF is exactly midway between the harmonics of the reference.

As mentioned above, the typical deficiencies of the conventional sampling phase detector 10 with respect to current and future applications include:
1. limited bandwidth (2-3 GHz bandwidth);
2. large footprint (2.0″×0.7″);
3. sub-optimum balun performance causing unequal strobes (pulses) which, in turn, causes the sampling diode bridge to perform poorly, leading to unequal charge storage in the respective RC networks;
4. poor RF isolation between the LO and RF/IF ports leading to phase noise degradation;
5. circuit complexity (typically needing as many as 22 discrete components and many wire bonds); and
6. high cost and low manufacturing yield due to the above limitations
   FIG. 2 is a block diagram showing a broadband sub-harmonic sampling phase detector implemented in accordance with an illustrative embodiment of the teachings of the present invention. The inventive sampling phase detector is based on planar technology by taking advantage of the unique balanced properties of slotline, coupled slotline and hybrid T slotline together with broadband slotline to CPW transitions. The inventive phase detector includes several planar integrated components including an ultra wideband grounded slotline hybrid T junction (balun), a phase bridge, a coupled grounded slotline delay (impulse sharpener) and finally, a broadband grounded transition from CPW to coupled slotline. Coplanar and slotline waveguides are known in the art. See U.S. patent application Ser. No. 10/425,263 entitled “Compact Broadband Balun,” filed Apr. 29, 2003, by Reza Tayrani and Kenneth. A. Essenwanger (Atty. Docket No. PD-01W172, the teachings of which are incorporated by reference herein.

Thus, the inventive phase detector 140 is shown in FIG. 2 with a slotline impulse generator 160, a sampling circuit 180 and a video amplifier 190. Both the impulse generator 160 and the sampling circuit 180 are fabricated on a multi-layer alumina substrate (not shown) using a grounded slotline and grounded coplanar waveguide (GCPW) line technology.

Thus, key novel elements of the inventive phase detector include the grounded slotline/CPW medium impulse generator 160, and the slotline/CPW medium sampling circuit 180. The sampling circuit 180, consists of an ultra wideband hybrid T junction (balun) 182, a phase bridge 184, a coupled slotline delay (impulse sharpener) 186 and a broadband transition from CPW to coupled slotline. The function of the combined circuits is to create two differential impulses for gating (turning on/off) the quad Schottky diodes and therefore sampling the RF signal at the rate of reference frequency.

A video amplifier 190 is included per conventional teachings.

In the preferred embodiment, the slotline impulse generator 160 uses a step recovery diode (SRD) to generate sub-nanosecond differential impulses. Novel broadband coplanar waveguide (CPW) to slotline transition (input port) and slotline to CPW (output ports) were included to maintain sharp impulses with minimum ringing and inter-pulse distortion.

An important element of the differential slotline impulse generator 160 is the slot line T junction and its associated wideband transitions. Such a miniature device acts as an ultra broadband (DC-20 GHz) balun. The slotline T-junction has a unique field pattern property. That is, when power is fed into its arm (1), it will act as a differential divider by producing two differential (anti-phase) signals of equal amplitudes in the other two arms. As shown in FIG. 3, the SRD diode is placed on the input arm of the slotline T-junction (arm 1) Because of the ultra broadband nature of this balun, the integrity of the SRD pulses is maintained.

FIG. 3 is a diagram of a slotline impulse generator and hybrid T junction implemented in accordance with an illustrative embodiment of the teachings of the present invention. The generator 160 includes a step recovery diode 162 surface mounted on a substrate 164. The SRD 162 is mounted closely to the CPW/slot transition. That is, the SRD sees a grounded coplanar waveguide metallization 166 in one direction and a grounded slotline metallization in the other. The hybrid T junction is shown at 182.

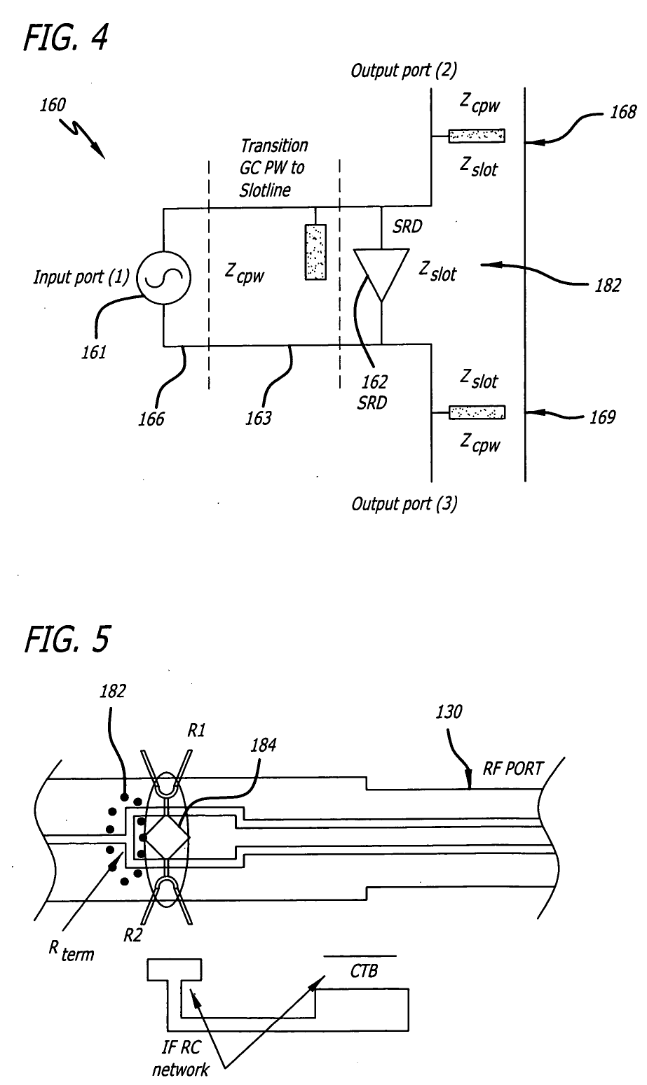

FIG. 4 is an equivalent circuit representation of the impulse generator shown in FIG. 3. In the illustrative embodiment, the SRD 162 is excited by a source 161 of a reference signal (e.g. at 93.1 MHz). The reference signal causes the junction capacitance of the SRD 162 to charge and discharge during each cycle of the reference signal. The SRD diode discharge is a snapping action which produces a sharp pulse having duration in the range of 30-100 Pico-seconds. This pulse propagates in the balanced slotline towards the slotline hybrid T-junction 182 and then propagates as two differential pulses along each arm of the T-junction 168, 169.

It is interesting to note that in accordance with the present teachings, the slotline impulse generator 160 operates under a self-biased condition and therefore needs only one component, an SRD, as shown in FIG. 3.

FIG. 5 is a diagram showing a layout of an illustrative implementation of the hybrid T junction and the phase bridge of the inventive phase detector.

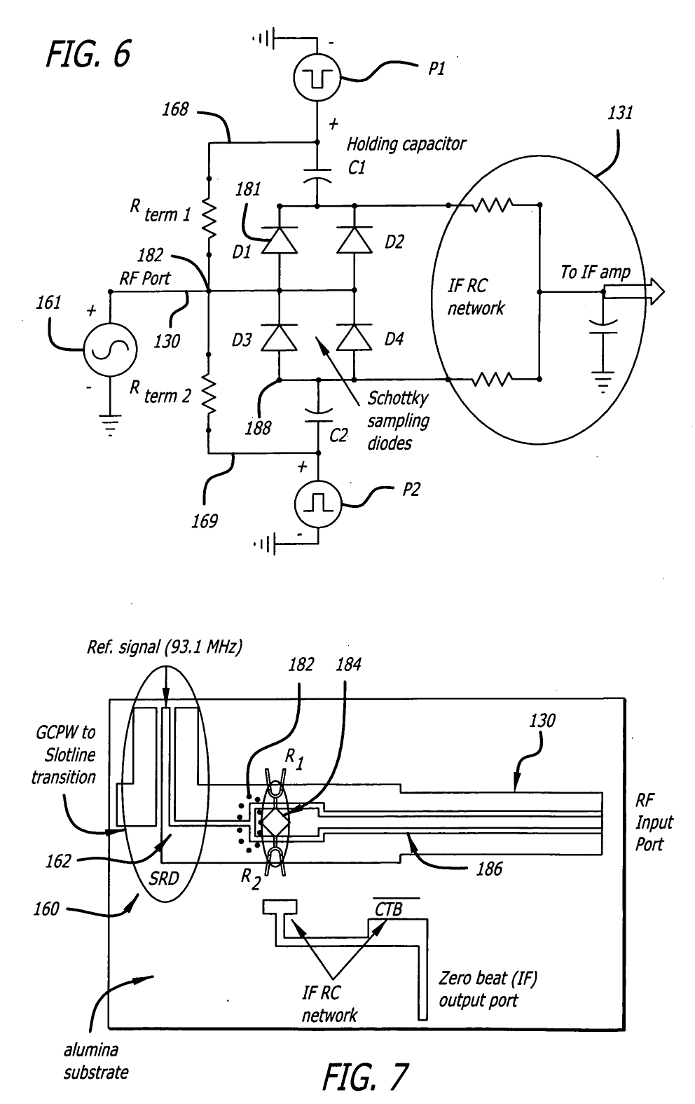

FIG. 6 is an equivalent circuit representation of the phase bridge of FIG. 5. As illustrated in FIGS. 5 and 6, the phase bridge 184 includes two identical parts 181 and 183. Each part 181 and 183 has two parallel Schottky sampling diodes D1 and D2 and D3 and D4, holding capacitors C1 and C2 and a terminating resistor Rₜₑᵣₘ₁ and Rₜₑᵣₘ₂, respectively mounted across the hybrid T-junction slotline. The slotline hybrid junction 182 converts the output of the impulse generator 160 into two balanced pulses and it operates based on the principle of a balanced single and coupled slotline. Therefore, after emerging from hybrid junction, the impulse propagates as two balanced pulses P₁ and P₂ of opposite polarity and equal amplitudes.

The two parts of the sampling phase bridge shown in FIG. 6 appear in series with respect to the LO port (Ref signal port and in parallel with respect to the RF and IF ports 130 and 131 respectively. This is due to the inherent properties of E-plane slotline T-junction that has the properties of a series T-junction, where the two arms electric fields are equal in amplitude but in anti-phase at points equidistance from the junction.

Also, as shown in FIG. 6, the IF RC network is designed to act as an IF low pass filter with a 3-dB cut-off frequency of less than half of the Ref. signal at LO port. Note that while the balanced pulses, which gate the sampling phase bridge, propagate in a balanced slotline mode, the RF and IF signals travel in an unbalanced grounded CPW mode. This leads to inherent isolations between LO/RF and LO/IF ports.

FIG. 7 is a diagram showing a layout of an illustrative implementation of the integrated broadband sampling phase detector implemented in accordance with the present teachings.

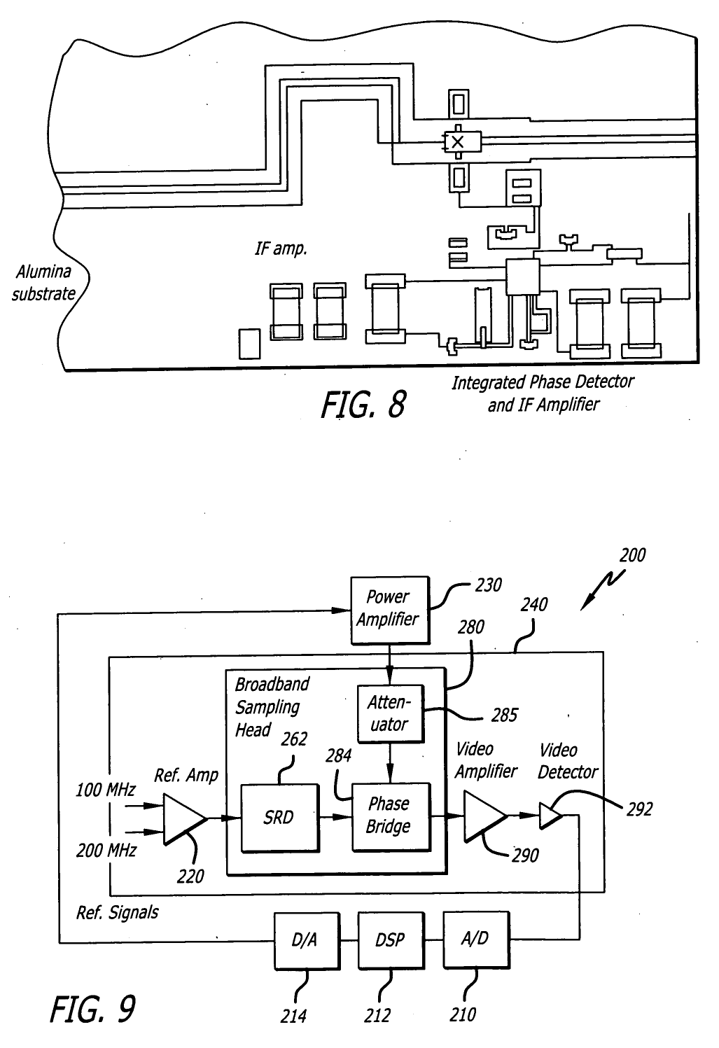

FIG. 8 shows an illustrative implementation of the actual device when fully fabricated and integrated with a video amplifier and its associated bias circuits.

The bandwidth of the sampling circuit 180 is one of the most important design parameters and is mostly influenced by the duration and the integrity of differential pulses generated by the impulse generator for gating the Schottky diodes. Adjustment of the length of the slotlines leads to a reflection of the propagating wave. The reflected wave interferes with the propagating wave and leads to a sharpening of the pulses. Thus, by adjustment of the lengths of the coupled slotlines (186), the pulses are sharpened and the bandwidth is broadened.

Normally, exact estimation of sampling circuit (or sampling head) bandwidth is complicated since it is influenced by several factors and interdependencies, including, gating-time duration, pulse rise time, reflections, and high frequency effects such as dispersion. However, an approximate bandwidth can be determined as:
BW˜350/Tg (GHz)
where T_{g} is the gating time in pico-seconds (ps).

For example, in an illustrative implementation, the SRD 162 has a nominal transition of time 30-100 ps. To enhance the sampling bandwidth above 20 GHz operation, a bond wire may be used across the two coupled slotline (the delay line section) to provide a short circuit to the incoming pulses. The reflected pulses arrive at the hybrid junction after a certain time and each will be combined with the other incident pulses to form a shorter duration pulse. The width of the reflected pulses at the hybrid T-junction is set by the propagation time through the short-circuited delay line.

Smart Sampling Phase Detector:

To detect and sense spurious signals or any oscillations generated within a circuit, i.e. a power amplifier, an integrated smart phase detector chip is needed. Such a chip will be able to self assess, detect and eliminate any unwanted spurious signals and thereby assure the signal integrity of the amplifier's output performance.

FIG. 9 shows an illustrative implementation of a programmable sub-harmonic phase detector in accordance with the present teachings. The programmable implementation 200 includes a sampling head 280 implemented in accordance with conventional teachings with the exception that an attenuator 285 is provided between an RF port not shown and the phase bridge 284. A video detector 292 detects the output of the video amplifier 290. The output of the video detector 292 is digitized by an analog to digital (A/D) converter and input to a digital signal processor (DSP) 212. Those skilled in the art will appreciate that the DSP could be replaced with a general-purpose microprocessor, discrete logic or other suitable processor without departing from the scope of the present teachings. The DSP 212 analyzes the output of the sampling head and provides an error signal to a power amplifier 230 via a digital to analog converter 214. The error signal is amplified and input to the sampling circuit 280 via the attenuator 285. Thus, the implementation of FIG. 9 is well adapted to effect temperature compensation of a sampling circuit of conventional design.

In the best mode and most general case, the programmable phase detector is implemented with the phase detector of the present invention illustrated in FIGS. 2-7 above.

Thus, the present invention has been described herein with reference to a particular embodiment for a particular application. The inventive phase detector may be fabricated in a conventional manner using computer aided (CAD) design, electromagnetic (EM) simulation, and time and frequency domain analysis. Those having ordinary skill in the art and access to the present teachings will recognize additional modifications, applications and embodiments within the scope thereof. For example, while the present teachings may be implemented in a highly integrated homogeneous chip using either SiGe BICMOS or CMOS technology, the invention is not limited thereto. The present teachings may be implemented in other technologies without departing from the scope thereof.

It is therefore intended by the appended claims to cover any and all such applications, modifications and embodiments within the scope of the present invention.

1. A phase detector comprising:
a substrate;
an impulse generator fabricated on the substrate; and
a sampling circuit operationally coupled to the generator and disposed on the substrate.

2. The invention of claim 1 wherein the substrate is a multi-layer alumina structure.

3. The invention of claim 1 wherein the impulse generator and the sampling circuit are fabricated on the substrate using grounded slotline technology.

4. The invention of claim 1 wherein the impulse generator and the sampling circuit are fabricated on the substrate using grounded coplanar waveguide technology.

5. The invention of claim 1 wherein the impulse generator is a slotline impulse generator.

6. The invention of claim 5 wherein the impulse generator includes a step recovery diode.

7. The invention of claim 6 wherein the impulse generator further includes a coplanar waveguide to slotline transition at an input port thereof.

8. The invention of claim 7 wherein the impulse generator further includes a slotline to coplanar waveguide at an output port thereof.

9. The invention of claim 1 wherein the sampling circuit includes a slotline hybrid T junction.

10. The invention of claim 9 wherein the junction is an ultrawideband grounded slotline hybrid T junction.

11. The invention of claim 9 wherein the hybrid T junction is coupled to the impulse generator.

12. The invention of claim 11 wherein the sampling circuit includes a phase bridge coupled to the hybrid T junction.

13. The invention of claim 12 wherein the sampling circuit includes a slotline coupled delay.

14. The invention of claim 13 wherein the coupled delay is a grounded coupled slotline delay.

15. The invention of claim 13 wherein the sampling circuit further includes a broadband transition from coplanar waveguide to coupled slotline.

16. The invention of claim 1 further including a video amplifier coupled to the sampling circuit.

17. A programmable sampling phase detector comprising:
a phase detector;
a power amplifier coupled to an input of the phase detector;
an analog to digital converter coupled to an output of the phase detector;
a processor coupled to the analog to digital converter; and
a digital to analog converter coupled to the processor and the amplifier.

18. The invention of claim 17 wherein the phase detector includes:
a substrate;
an impulse generator fabricated on the substrate; and
a sampling circuit operationally coupled to the generator and disposed on the substrate.

19. The invention of claim 17 wherein the substrate is a multi-layer alumina structure.

20. The invention of claim 17 wherein the impulse generator and the sampling circuit are fabricated on the substrate using ground slotline technology.

21. The invention of claim 17 wherein the impulse generator and the sampling circuit are fabricated on the substrate using grounded coplanar waveguide technology.

22. The invention of claim 17 wherein the impulse generator is a slotline impulse generator.

23. The invention of claim 22 wherein the impulse generator includes a step recovery diode.

24. The invention of claim 23 wherein the impulse generator further includes a coplanar waveguide to slotline transition at an input port thereof.

25. The invention of claim 24 wherein the impulse generator further includes a slotline to coplanar waveguide at an output port thereof.

26. The invention of claim 17 wherein the sampling circuit includes a slotline hybrid T junction.

27. The invention of claim 26 wherein the junction is an ultrawideband grounded slotline hybrid T junction.

28. The invention of claim 26 wherein the hybrid T junction is coupled to the impulse generator.

29. The invention of claim 28 wherein the sampling circuit includes a phase bridge coupled to the hybrid T junction.

30. The invention of claim 29 wherein the sampling circuit includes a slotline coupled delay.

31. The invention of claim 30 wherein the coupled delay is a grounded slotline delay.

32. The invention of claim 30 wherein the sampling circuit further includes a broadband transition from coplanar waveguide to coupled slotline.

33. The invention of claim 17 further including a video amplifier coupled to the sampling circuit.

34. An impulse generator comprising:
a ground coplanar waveguide input line;
a step recovery diode mounted across said input line; and
a ground slotline output line coupled to said grounded coplanar waveguide input line.

35. A method for detecting a phase of a signal including the steps of:
providing a substrate;
fabricating an impulse generator on the substrate;
providing a sampling circuit on the substrate, the sampling circuit operationally coupled to the generator; and
feeding an input signal and a reference signal to the sampling circuit and detecting the output thereof.
